(19) United States
(12) Patent Application Publication
(10) Pub. No.: US 2024/0332058 A1
(43) Pub. Date: Oct. 3, 2024

(54) SUBSTRATE SUPPORT ASSEMBLY

(71) Applicant: Applied Materials, Inc., Santa Clara, CA (US)

(72) Inventors: Sathiyamurthi GOVINDASAMY, Coimbatore (IN); Harish PENMETHSA, Dublin, CA (US); Suresh PALANISAMY, Coimbatore (IN)

(21) Appl. No.: 18/436,846

(22) Filed: Feb. 8, 2024

(30) Foreign Application Priority Data
Mar. 28, 2023 (IN) 202341022458

(51) Int. Cl. H01L 21/687

(52) U.S. Cl. CPC H01L 21/68742

(57) ABSTRACT

A support assembly for supporting a substrate in a processing station includes a housing, a pin, a plurality of bearing elements, and a retaining member. The housing includes a bore, a groove formed on an exterior surface of the housing, and a plurality of windows disposed in the groove that intersect the bore. The pin is disposed in the bore and moveable between a retracted position and an extended position. The pin includes a shaft including a plurality of bearing surfaces. The plurality of bearing elements are at least partially disposed in a corresponding window. Each bearing element includes an outer surface configured to engage a corresponding bearing surface of the shaft. The plurality of bearing elements and bearing surfaces cooperate to maintain an angular orientation of the pin as the pin moves between the retracted position and the extended position. The retaining member is disposed in the groove.

### CROSS-REFERENCE TO RELATED APPLICATIONS

This application claims the benefit under 35 U.S.C. § 119(a) of Indian Provisional Patent Application No. 202341022458 filed Mar. 28, 2023, the entire contents of which are incorporated by reference herein.

### BACKGROUND

### Field

Embodiments of the present disclosure generally relate to a substrate support pin for use in, e.g., semiconductor substrate processing.

### Description of the Related Art

Substrates (such as semiconductor substrates) are conventionally processed in a substrate processing system that includes multiple processing stations to process the substrate. To facilitate transfer of the substrate between the processing stations, support members, such as a plurality of lift pin assemblies for example, are mounted within a support pedestal within the processing station so that the substrate may be lifted from the support pedestal. This allows a transfer mechanism such as a robot blade to slide underneath a back side of the substrate and lift the substrate off the support members.

Conventional lift pin assemblies that restrain the rotation of a lift pin include a lift pin disposed within a bore of a housing. The housing has a bore shaped to engage the surface of the pin to stop the pin from freely rotating relative to the housing. As a result, the pin contacts and rubs against the bore of the housing during the axial movement of the pin. This contact between the pin and housing results in particle generation that can interfere with the process being performed within the processing station. Additionally, this contact progressively wears the surface of the pin and housing which increases the friction therebetween, which results in increased particle generation and can result in the pin vibrating within the housing as it scrapes along the surface of the bore. This vibration can cause damage to the substrate. Further, if one or more pins used to raise and lower a substrate are vibrating, then the vibration can cause the substrate to fall off the pins which can damage the substrate. In such a case, processing may need to be halted until the fallen substrate is retrieved and the faulty pins are replaced. Additionally, a spring may be disposed in the housing to bias the pin in a retracted position. The spring force has a tendency to apply a torsional force to the pin which increases the friction force between the pin and housing. The pin may become locked, stuck, or jerk due the frictional forces caused by the worn area of contact between the damaged pin and housing and/or the spring force. A pin becoming locked, stuck, or jerking can result in a substrate being dropped and/or otherwise damaged.

Therefore, there is a need in the art for a lift pin that is rotationally restrained with reduced particle generation and instances of failure, such as becoming locked, stuck, jerking, or vibrating during use. Additionally, there is a need in the art to increase the longevity of the lift pin to reduce maintenance of the processing station in which the lift pin is installed.

### SUMMARY

The present disclosure generally relates to support assemblies configured to support and move a substrate within a substrate processing station.

In one embodiment, a support assembly for supporting a substrate in a processing station includes a housing, a pin, a plurality of bearing elements, and a retaining member. The housing includes a bore, a groove formed on an exterior surface of the housing, and a plurality of windows disposed in the groove that intersect the bore. The pin is disposed in the bore and moveable between a retracted position and an extended position. The pin includes a shaft including a plurality of bearing surfaces. The plurality of bearing elements are at least partially disposed in a corresponding window of the plurality of windows. Each bearing element includes an outer surface configured to engage a corresponding bearing surface of the shaft. The plurality of bearing elements and bearing surfaces cooperate to maintain an angular orientation of the pin as the pin moves between the retracted position and the extended position. The retaining member is disposed in the groove.

In one embodiment, a support assembly for supporting a substrate in a processing station includes a ceramic housing, a ceramic pin, a plurality of bearing elements, and a retaining member. The ceramic housing includes a bore, a groove formed on an exterior surface of the housing, a plurality of windows disposed in the groove that intersect the bore, and a shoulder at an upper end configured to engage with a surface of a pedestal. The ceramic pin is disposed in the bore and moveable between a retracted position and an extended position. The pin includes a shaft including a plurality of bearing surfaces and a head with a supporting surface configured to engage with a bottom edge of a substrate. The plurality of bearing elements are at least partially disposed in a corresponding window of the plurality of windows. Each bearing element includes a ceramic roller with an outer surface configured to engage a corresponding bearing surface of the shaft. The plurality of bearing elements and bearing surfaces cooperate to maintain the support surface in alignment with the bottom edge of the substrate as the pin moves between the retracted position and the extended position. The retaining member is disposed in the groove.

In one embodiment, support assembly for supporting a substrate in a processing station includes a ceramic housing, a ceramic pin, and a plurality of bearing elements. The ceramic housing including an outer surface, an inner surface defining a bore, and a plurality of first windows extending from the outer surface and the inner surface. The ceramic pin is disposed in the bore and moveable between a retracted position and an extended position, wherein the ceramic pin includes a pin shaft including a plurality of bearing surfaces and a head with a supporting surface configured to engage with a bottom edge of a substrate. The plurality of bearing elements are at least partially disposed in a corresponding window of the plurality of first windows. Each bearing element includes a bearing shaft formed integrally with the ceramic housing and a ceramic roller with an outer surface configured to engage a corresponding bearing surface of the pin shaft. The plurality of bearing elements and bearing surfaces cooperate to maintain the support surface in alignment with the bottom edge of the substrate as the ceramic pin moves between the retracted position and the extended position.

In one embodiment, a method of moving a substrate includes extending a plurality of pins of a plurality of support assemblies from a retracted position to engage a bottom edge of a substrate that is engaged with a support surface of a pedestal. Each pin is rotationally locked by a plurality of bearing elements engaged with the pin that are disposed within a housing of each support assembly. The method further includes extending the plurality of pins to an extended position to lift the substrate above the pedestal. The method further includes disengaging the substrate from the plurality of lift pins in the extended position.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A is an isometric view of a support assembly according to one embodiment.

FIG. 1B is an isometric view of a housing of the support assembly, according to the embodiment shown in FIG. 1A.

FIG. 1C is a partial cross-sectional view about the section line C-C in FIG. 1A showing an arrangement of bearing elements and a cross-section of the shaft of the support assembly, according to the embodiment shown in FIG. 1A.

FIG. 2A is a partial cross-sectional view of a support assembly disposed in a pedestal showing the support assembly in a retracted position according to one embodiment.

FIG. 2B is a partial cross-sectional view of the support assembly disposed in the pedestal showing the support assembly, according to the embodiment shown in FIG. 2A, in an extended position.

FIG. 3 is a partial cross-sectional view of a support assembly with a set of bearing elements that includes three bearing elements according to one embodiment.

FIG. 4 illustrates a partial cross-sectional view of a support assembly with a set of bearing elements arranged in a triangular configuration according to one embodiment.

FIG. 5 illustrates a partial cross-sectional view of a support assembly with a set of bearing elements including a channel arranged in a diamond configuration according to one embodiment.

FIG. 6 illustrates a partial cross-sectional view of a support assembly with a set of bearing elements including a channel arranged in a triangular configuration according to one embodiment.

FIG. 7 illustrates a cross-sectional view of an exemplary support assembly showing a set of bearing elements arranged to restrain the rotation of a pin according to one embodiment.

FIG. 8 illustrates a cross-sectional view of an exemplary processing station.

FIG. 9 is a flow chart of a method of moving a substrate using a plurality of substrate assemblies.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to substrate manufacturing and, more particularly, to systems and methods for raising and lowering the substrate within a processing station of a substrate processing system.

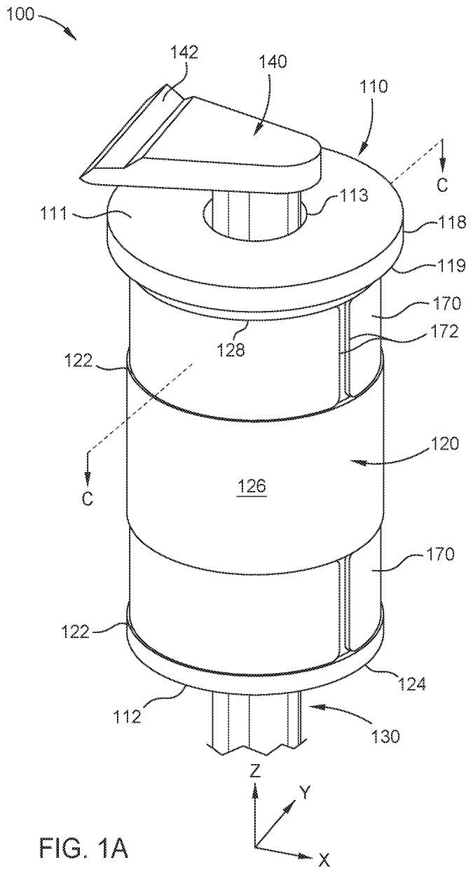

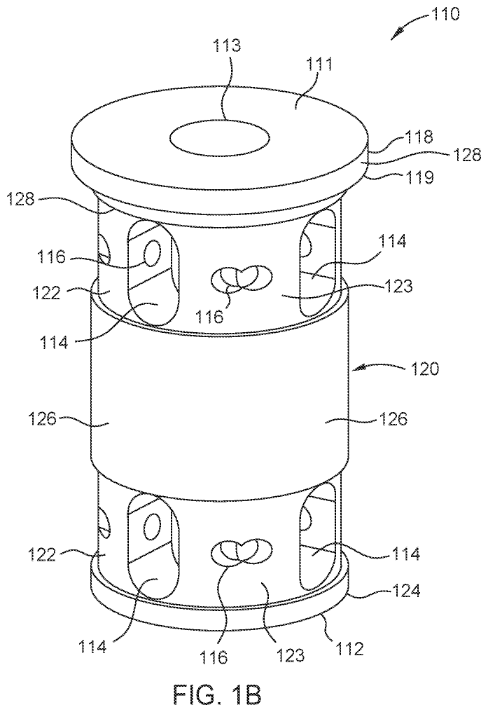

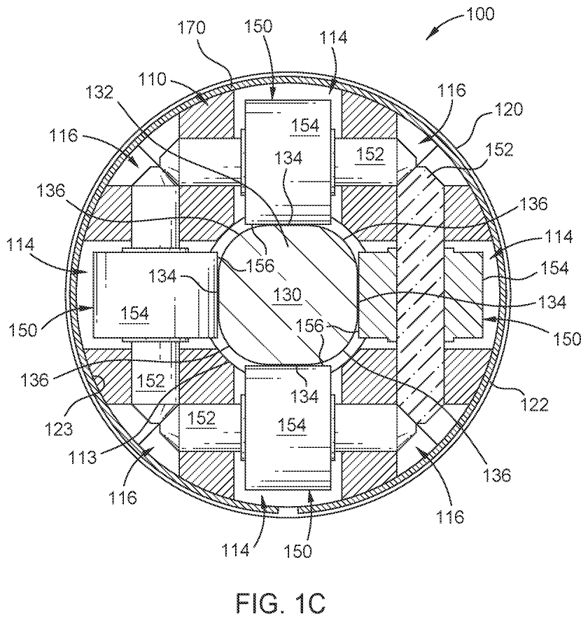

FIG. 1A discloses an isometric view of one embodiment of a support assembly 100. The support assembly 100 includes a housing 110, a pin 130, a plurality of bearing elements 150 (FIG. 1C), and two retaining members 170. The support assembly 100 is configured to facilitate axial movement of the pin 130 to raise and lower a substrate. The support assembly 100 may be disposed in a pedestal of a substrate processing chamber. FIG. 1A includes an X,Y,Z coordinate system to show the orientation of the pin 130.

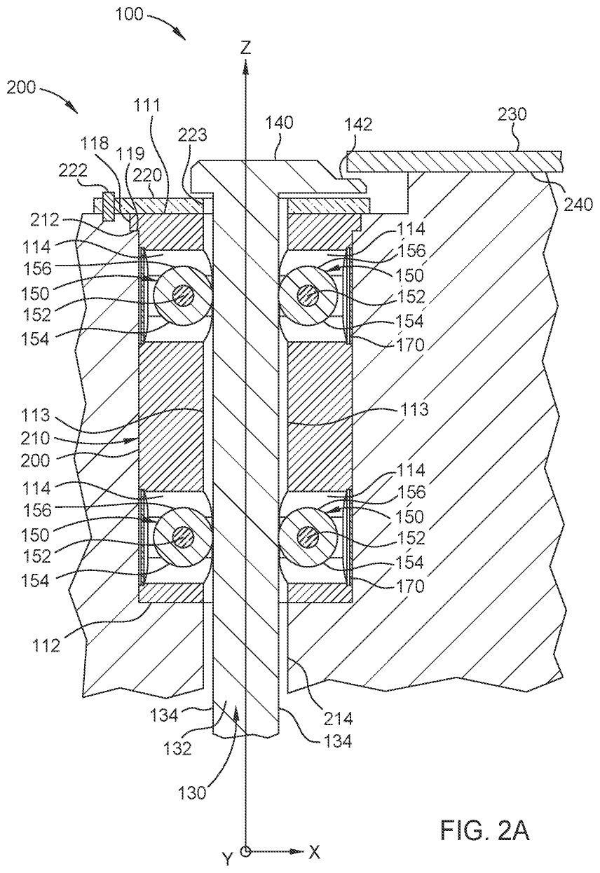

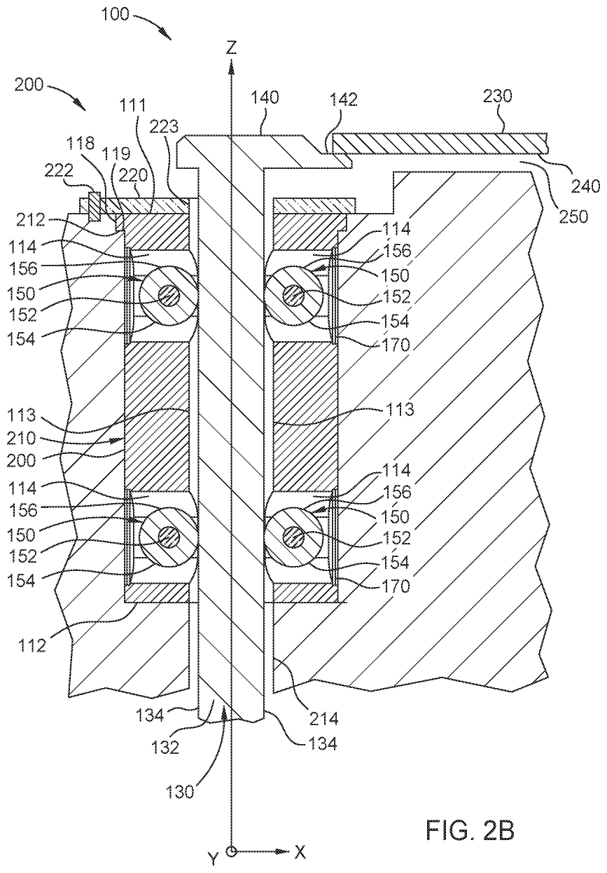

FIG. 1B illustrates an isometric view of the housing 110 without the other components of the support assembly 100. The housing 110 is an annular member with a longitudinal bore 113 that extends from an upper end 111 to a lower end 112 of the housing 110. The bore 113 is defined by an inner surface of the housing 110. The housing 110 is preferably a cylindrical tube as shown in FIG. 1B. The upper end 111 may include a shoulder 118 that protrudes past the outer diameter of an exterior side surface 120 of the housing 110. The shoulder 118 includes a shoulder surface 119 that is configured to abut a surface of the pedestal (see FIG. 2A) to support the weight of the housing 110, bearing elements 150 (FIG. 1C), and retaining members 170 (FIG. 1A) when the support assembly 100 is installed in the pedestal.

The exterior side surface 120 extends from the upper end 111 to the lower end 112. The exterior side surface 120 shown in FIG. 1B is defined by one or more grooves 122, a lower side surface 124, a middle side surface 126, and an upper side surface 128. Each groove 122 is shown as a circumferential groove formed in the exterior side surface 120. The lower side surface 124, the middle side surface 126, and the upper side surface 128 may have the same or substantially the same outer diameter. The one or more grooves 122, such as the two grooves 122 shown in FIG. 1B, are formed in the side of the housing 110 and separated from one another by the middle side surface 126. The groove 122 closest to the lower end 112 (e.g., lower groove) is separated from the lower end 112 by the lower side surface 124. Additionally, groove 122 closest to the upper end 111 (e.g., upper groove) is separated from the upper end 111 by the upper side surface 128.

Each groove 122 includes a groove surface 123 that is recessed with respect to the side surfaces 124, 126, 128. A plurality of windows 114 are formed in each groove 122 that extend radially from the groove surface 123 and intersect with the bore 113. Each window 114 is aligned with another window 114 on the opposing side of the bore 113. Cut outs 116 are also formed in the groove surface 123 of each groove 122 on opposing sides of the windows 114. For example, the housing 110 may include four windows in each groove as shown in FIGS. 1B and 1C to accommodate four bearing elements 150.

FIG. 1C illustrates a partial cross-section along the line C-C in FIG. 1A looking toward the lower end 112. The pin 130 is engaged with one or more sets of bearing elements 150. The support assembly 100 includes two sets of bearing elements 150. Referring to FIGS. 1A-1C, the first set of bearing elements 150 are disposed in the windows 114 and cut outs 116 formed in the upper groove 122 and the second set of bearing elements 150 are disposed in the windows 114 and cut outs 116 formed in the lower groove 122. As shown in FIG. 1C, the windows 114 and bearing elements 150 are arranged in a square configuration. The bearing elements 150 are arranged to facilitate axial movement of the pin 130 relative to the housing 110 within the bore 113 as the pin 130 moves between a retracted position (FIG. 2A) and an extended position (FIG. 2B). The shape of the pin 130 and the arrangement of the bearing elements 150, however, cooperate to rotationally lock the pin 130 while permitting the pin 130 to move between the retracted position and the extended position to maintain an angular orientation of the pin 130. In other words, the pin 130 is restrained from rotating about the Z-axis as it moves between the extended and retracted positions.

FIG. 1C only shows one bearing element 150 in cross-section. Each bearing element 150 includes a shaft 152 (e.g., bearing shaft) disposed in a roller 154. Each shaft 152 extends into an opposing cut out 116 that is formed though the housing 110. Thus, the shaft 152 is supported on opposing sides of the corresponding roller 154 by the housing 110. Each roller 154 is disposed in a corresponding window 114 and partially extends into the bore 113 to engage the pin 130. Each roller 154 has an outer surface 156 configured to engage a corresponding bearing surface 134 of the pin 130. The outer surface 156 complements the bearing surface 134, in that the outer surface 156 is flat similarly to the flat bearing surface 134. Each roller 154 is rotatable independently of the other rollers 154 relative to the housing 110 to facilitate axial movement of the pin 130. The rollers 154 are held into place via a friction fit facilitated by the ends of the shafts 152 arranged opposite one another within the cut outs 116 formed within the housing 110. Additionally, the ends of each shaft 152 may be chamfered to form a conical shape as shown in FIG. 1C.

The pin 130 includes a shaft 132 (e.g., pin shaft) that is disposed in the bore 113. The shaft 132 includes four flat bearing surfaces 134 that correspond to a respective roller 154. The bearing elements 150 are arranged in the housing 110 such that the outer surface 156 of each roller 154 is parallel with a corresponding bearing surface 134 of the pin 130. This arrangement restrains rotation of the pin 130 within the bore 113 because the opposing surfaces of the pin 130 and rollers 154 will contact one another to limit rotation in the event that the pin 130 tries to rotate about its longitudinal axis (e.g., Z-axis). Additionally, the shaft 132 and rollers 154 are sized to restrain rotation of the pin 130, in that the outer diameter of the shaft 132 is large enough to restrain the shaft 132 from freely rotating (e.g., being able to make one or more complete revolutions in any rotational direction) within the gap between the four rollers 154.

In some embodiments, the shaft 132 is sized such that the four bearing surfaces 134 are constantly engaged with a corresponding roller 154. Alternatively, the shaft 132 may be sized such that a clearance is present between the outer surface of the shaft 132 and one or more rollers 154.

As shown in FIG. 1C, the shaft 132 has a cross-section that resembles a square with rounded edges 136 between the flat bearing surfaces 134. In other words, the bearing surfaces 134 are arranged in a square configuration. The shaft 132 may include the rounded edges 136 to facilitate fitting the shaft 132 into the bore 113. In some embodiments, the shaft 132 has a square cross-section without rounded edges 136.

The partial cross-section in FIG. 1C is representative of the cross-section of the second set of bearing elements 150 disposed in the windows 114 and cut outs 116 formed in the lower groove 122.

A retaining member 170 is disposed in each groove 122 after the bearing elements 150 are installed in the housing 110. The retaining member 170 encloses the bearing elements 150 within the housing 110 and prevents the bearing elements 150 from falling out. The retaining member 170 may be a C-shaped retaining spring as shown in FIG. 1A. The retaining member 170 is snugly engaged with the groove surface 123 to prevent the retaining member 170 from being separated from the groove 122 while the support assembly 100 is installed in a pedestal. The opposing ends 172 of the retaining member 170 may be engaged or separated by a small gap when installed on the housing 110. Additionally, the retaining member 170 has a thickness less than or equal to the depth of the groove 122. In other words, the retaining member 170 does not protrude from the groove 122 to prevent the retaining member 170 from interfering with the installation of the support assembly 100 into a pedestal. In some embodiments, the retaining member 170 is a snap ring.

Referring back to FIG. 1A, the pin 130 includes a head 140 connected to the upper end of the shaft 132. The head 140 includes a support surface 142 configured to support the underside of a substrate (not shown) about the periphery of the substrate (e.g., the bottom edge of the substrate). The head 140 is not a rounded or flat surface of the upper end of the shaft 132 of the pin 130. Instead, the head 140 of the pin 130 extends beyond the periphery of the shaft 132 and may extend beyond the edge of the bore 113 and above the upper end 111 of the housing 110 as shown in FIG. 1A. In some embodiments, the head 140 may extend beyond the edge (e.g., periphery) of the shoulder 118. In some embodiments, and as shown in FIG. 1A, the head 140 is a non-uniform body. While the head 140 is non-uniform, the head 140 may be symmetrical, as shown in FIG. 1A, about a line of symmetry. The support surface 142 may be located in a lateral position relative to where the shaft 132 joins with the head 140. In other words, the head 140 extends beyond the periphery of the shaft 132 with the support surface 142 located laterally away from the shaft 132 such that the support surface 142 is not disposed directly above the upper end of the shaft 132.

The support assembly 100 maintains the angular orientation of the pin 130, and thus the head 140, about the Z-axis (e.g., longitudinal axis) as the pin 130 moves axially along the Z-axis because the pin 130 is restrained from rotating due to the bearing elements 150 and corresponding bearing surfaces 134. In other words, the orientation of the pin 130, and thus the head 140, with respect to their position on the X, Y axes is maintained while the pin 130 is translated along the Z-axis. Maintaining the angular orientation of the head 140 during the translation of the pin 130 is keeps the support surface 142 in contact with the underside of the substrate to facilitate raising and lowering the substrate. Maintaining the angular orientation of the pin 130 maintains the support surface 142 in alignment with substrate and housing 110 during the axial movement of the pin 130. If the pin 130 were permitted to freely rotate, then the support surface 142 could become misaligned with the bottom edge of the substrate which could lead to the substrate being dropped.

In some embodiments, the support assembly 100 maintains the angular orientation of the head 140 relative to the substrate and the housing 110 by completely preventing any rotational movement of the pin 130 relative to the housing 110. In other words, the pin 130 is translated straight up and down the Z-axis without a change of an angular position of the pin 130 relative to the X, Y axes. In some embodiments, the support assembly 100 maintains the angular orientation of the head 140 even though the shaft 132 is able to partially rotate (e.g., wiggle) about the Z-axis as the pin 130 moves axially. For example, the pin 130 may wiggle slightly within the bore 113 if a clearance is present between a bearing surface 134 and a corresponding bearing element 150. However, this partial rotation is limited and is insufficient for the support surface 142 of the head 140 to become misaligned (e.g., disengaged) from the substrate as the pin 130 is moved axially to raise and/or lower the substrate. In other words, the angular orientation of the pin 130 may be maintained by keeping the angular position of the pin 130 within an acceptable range of rotation when the pin 130 is translated such that the support surface 142 remains aligned, and thus engaged, with the bottom edge of the substrate. For example, pin 130 may be permitted to rotate less than 1 degree, such as less than 0.5 degrees, about the Z-axis as the pin 130 is translated along the Z-axis. In some embodiments, the pin 130 is prevented from rotating less than 0.1 degrees. Additionally, rotation of the pin 130 causes the support surface 142 to rub against the underside of the substrate which can generate particulates that can interfere with the processing of the substrate. Thus, completely preventing rotation or limiting the wiggle of the pin 130 reduces particle generation caused by the contact of the head 140 with the substrate.

In some embodiments, the head 140 may be a uniform body extending from the upper end of the shaft 132 with a substrate supporting surface that contacts the underside of the substrate. For example, the head 140 may be a cylindrical pad with an outer diameter greater than the outer diameter of the shaft 132. The head 140 with the uniform body may contact the underside of the substrate at the periphery of the substrate or the support assembly 100 may be positioned such that the head 140 contacts the underside of the substrate at a location inset from the bottom edge of the substrate. Additionally, the head 140 may be a rounded or flat end of the shaft 132 with the substrate supporting surface being the upper end of the shaft 132 configured to engage with any portion of the underside of the substrate. Limiting or preventing the rotation of the pin 130 with a head that is a uniform body also reduces the amount of particles generated caused by the frictional contact of the head 140 with the substrate.

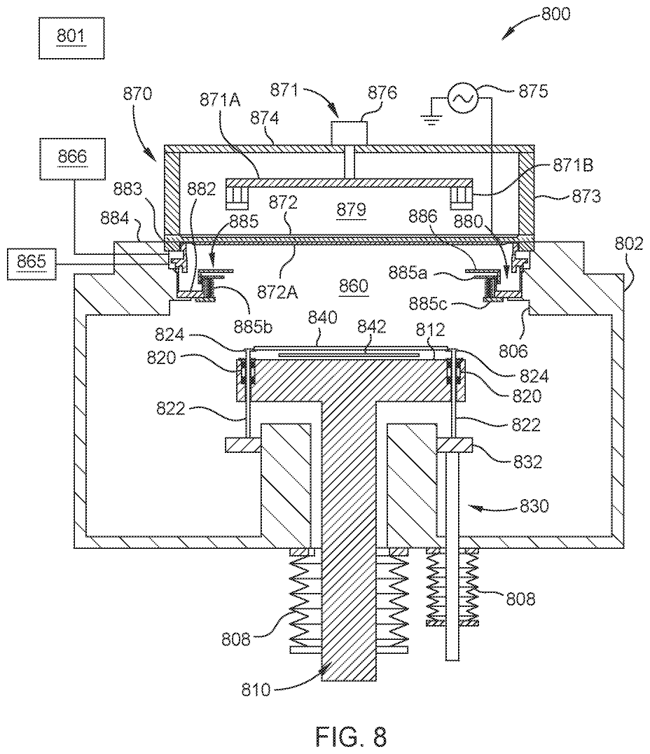

The lower end of the shaft 132 may be connected to a pin lift assembly that is used to move the pin 130 axially between the extended and retracted positions. For example, the pin lift assembly may be a lift plate (e.g., hoop) that is moved relative to the pedestal by an actuator. The lower end of the shaft 132 is attached to the lift plate. The movement of the lift plate causes the pins 130 to move with the lift plate. For example, the pin lift assembly is used to raise the lift pins 130 relative to the pedestal which causes the head 140 to lift into contact with the substrate. Additional movement of the pins 130 causes the substrate to be lifted above the pedestal such that a gap is present between the upper surface of the pedestal and the underside of the substrate. A blade of a robot is insertable into the gap underneath the substrate. An example of a pin lift assembly (see pin lift assembly 830) is shown in FIG. 8.

Alternatively, the lower end of the shaft 132 may not be connected to a pin lift assembly that moves the pin relative to the pedestal. Instead, the lower end of the shaft 132 may extend past the bottom surface of the pedestal and the pin 130 may be free hanging in within the housing 110. The pedestal may be lowered within the processing chamber to a transfer position, which causes the lower end of the shaft 132 to come into contact with the a surface on the bottom of the processing chamber. The contact of the lower end of the shaft 132 with the surface causes the pin 130 to be move relative to the pedestal to contact and lift the substrate above the pedestal. As a result, the substrate is supported above the surface of the pedestal by the pin 130 with a gap between the upper surface of the pedestal and the underside of the substrate. A blade of a robot is insertable into the gap underneath the substrate. The pin 130 can return to the retracted position under the influence of gravity once the pedestal is raised to disengage the lower end of the shaft 132 from the surface on the bottom of the processing chamber.

The housing 110, the pin 130, and the bearing elements 150, such as the roller 154, may each be made of a ceramic material. Without being bound by theory, it is believed that using a ceramic material reduces friction and thus reduces particle generation caused by frictional contact. Examples of ceramic materials include alumina, titanium nitride, silicon nitride, and silicon carbide. Therefore, it is believed that forming the housing 110, pin 130, and rollers 154 from a ceramic material increases the lifespan of the support assembly 100 and reduces the maintenance thereof.

The arrangement of the bearing elements 150 also prevents the shaft 132 of the pin 130 from contacting the surface of the bore 113. In other words, the outer surface of the shaft 132 only contacts the outer surface 156 of the rollers 154 which limits the surface area available to produce particles due to the frictional contact to the area of contact between the bearing surfaces 134 and the outer surface 156 of the rollers 154. Thus, the arrangement of the bearing elements 150 within the housing 110 eliminates the potential for particles to be generated by frictional contact between the moving pin 130 and the surface of the bore 113. Additionally, preventing contact between the pin 130 and the housing 110 (e.g., the surface of the bore 113) reduces the potential for vibrations caused by the wear and damage caused by repeated scraping of a length of the pin and with the housing experienced in conventional systems. Additionally, limiting the area of contact between the pin 130 with other components of the support assembly 100 (e.g., the bearing elements 150) increases the longevity of the support assembly 100 and thus reduces maintenance of the processing chamber that the support assembly 100 is installed within.

In some embodiments, and as shown in FIGS. 1A-1C, the support assembly 100 does not include a biasing member, such as a spring, to bias the pin 130 toward a position, such as the retracted position. A biasing member is not needed because the bearing elements 150 guide the axial movement of the pin 130, and the pin 130 returns to retracted position by a pin lift assembly or under the influence of gravity. Eliminating a biasing member eliminates the possibility of particle generation caused by frictional contact of the biasing member with the housing and/or pin. Additionally, eliminating the biasing member also eliminates the possibility of the spring force applying a torsional force that increases friction, and thus additional particle generation, between the pin 130 and the bearing elements 150 as the pin 130 moves axially. Furthermore, eliminating the biasing member and including the bearing elements 150 avoids a problem associated with conventional systems, where the spring force and the worn area of contact between the pin and housing would cause the pin to become locked, stuck, or jerk, which could result in the substrate being dropped.

In some embodiments, the substrate support assembly 100 may have only one set of bearing elements 150 and thus only one retaining member 170. Thus, the housing 110 will only have one groove 122 and one set of windows 114 and cut outs 116. In some embodiments, the support assembly 100 may have more than two sets of bearing elements 150. For example, the support assembly 100 may have three sets of bearing elements, with the housing including a third groove and a third set of windows 114 and cut outs 116 that the third set of bearing elements 150 are disposed within. The number of retaining members 170 corresponds to the number of distinct sets of bearing elements 150.

FIGS. 2A and 2B illustrate the support assembly 100 installed in a portion of a pedestal 200. The pedestal 200 can be installed in a processing chamber, such as processing station 800 shown in FIG. 8. FIG. 2A shows the pin 130 in a retracted position (e.g., lower position) beneath a substrate 230. FIG. 2B illustrates the pin 130 in an extended position (e.g., upper position) engaged with the substrate 230. Three or more support assemblies 100 may be installed in the pedestal 200 to raise and lower the substrate 230.

As shown in FIG. 2A, the pedestal 200 includes a recess 210 configured to receive the support assembly 100. The recess 210 may include a shoulder 212 configured to mate with the shoulder 118 of the housing 110. The recess 210 may also include a shaft portion 214 allowing the shaft to extend through the pedestal 200. The support assembly 100 may be retained in the recess 210 by a retainer plate 220 which includes a bore 223 aligned with the bore 113 of the housing 110. The retainer plate 220 may be attached to the pedestal 200 by one or more fasteners 222. The support assembly 100 is orientated in the recess 210 such that the support surface 142 is properly aligned with the substrate to facilitate raising and lowering the substrate

The bore 223 of the retainer plate 220 is sized such that the retainer plate 220 does not contact the shaft 132 during the axial movement of the pin 130. Preventing contact between the shaft 132 and retainer plate 220 during the axial movement of the pin 130 avoids particle generation that would be caused if the shaft 132 and retainer plate 220 were permitted to rub against one another during the movement of the pin 130. In some embodiments, the support assembly 100 is configured such that the underside of the head 140 is prevented from contacting the retainer plate 220 to avoid particle generation. For example, the pin 130 may be connected to a lift plate and the shaft 132 may have a length such that a clearance, as shown in FIG. 2A, is present between the underside of the head 140 and the retainer plate 220 when the pin 130 is in the retracted position.

A substrate 230 is shown engaged with an upper surface 240 of the pedestal 200. The upper surface 240 is part of the support surface of the pedestal 200 that supports the substrate 230 during processing. The substrate 230 overhangs the upper surface 240 above the support surface 142 of the head 140 while the pin 130 is in the retracted position. The upper surface 240 may be located at an elevation above the support assembly 100 in the recess 210 to keep the substrate 230 from contacting the support assembly 100 during processing.

After the substrate 230 is processed, the pin 130 may be raised axially from the retracted position to the extended position by a pin lift assembly (not shown) to place the substrate 230 above the upper surface 240 as shown in FIG. 2B. For example, the pins 130 of three or more support assemblies 100 may be simultaneously extended to lift the substrate 230. A robot, such as a blade of the robot, may be inserted into a gap 250 disposed between the underside of the substrate 230 and the upper surface 240. The robot may then lift the substrate off the support surface 142, or the pins 130 may be retracted to disengage the substrate 230 from the support surface 142.

In some embodiments, the pedestal 200 may also include a plurality of guide pins configured to raise and lower a cover ring (not shown) positioned closer to the edge of the pedestal than the support assemblies 100. These guide pins may lower the cover ring into engagement with the upper surface of the substrate once the pin 130 is in the retracted position to isolate the support assembly 100 from process gases. The guide pins also raise the cover ring to allow the pins 130 to move to the extended position without contacting the cover ring.

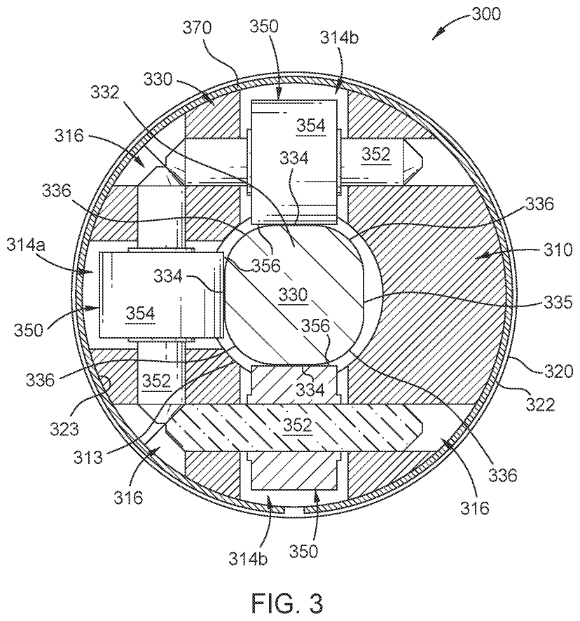

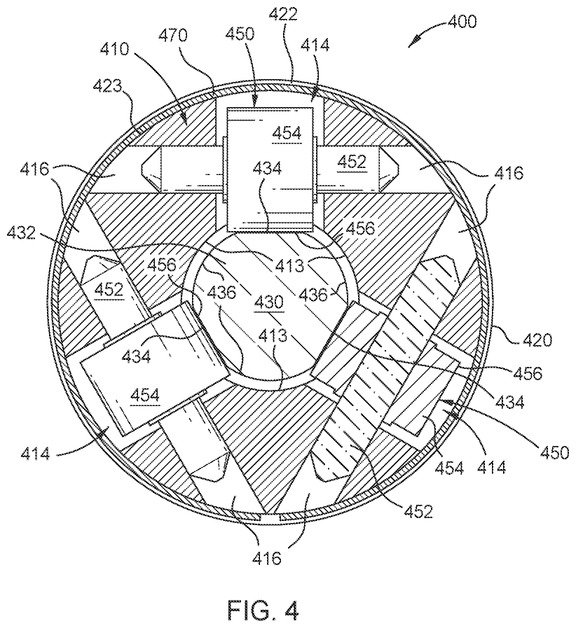

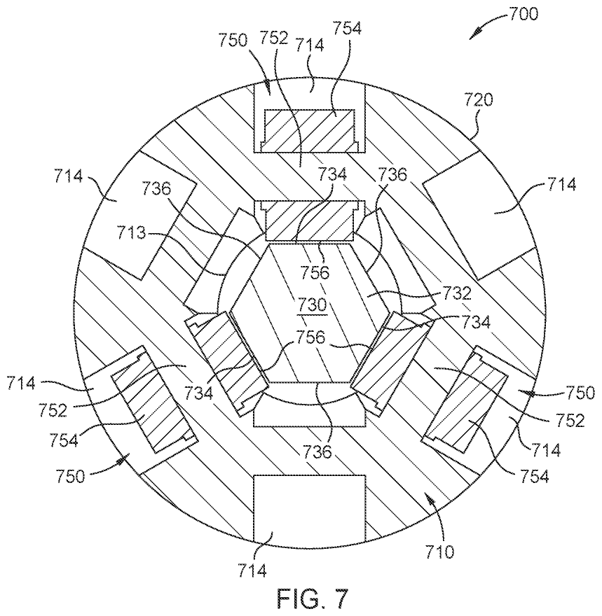

FIG. 3 and FIG. 4 illustrate alternative embodiments of a support assembly configured to maintain the angular orientation of the pin that includes a shaft with flat sides that engage with a corresponding flat surface of a bearing element. FIG. 7 also illustrates an embodiment of a support assembly configured to maintain the angular orientation of the pin that includes a shaft with flat sides that engage with a corresponding flat surface of a bearing element.

FIG. 3 is a partial cross-sectional view of a support assembly 300 showing a set of bearing elements 350 arranged to restrain rotation of a pin 330. Support assembly 300 includes one or more sets of bearing elements 350 that are similar to bearing elements 150. As shown, each set of bearing elements 350 in the support assembly 300 has three bearing elements 350. Only one bearing element 350 is shown in cross-section. Housing 310 is similar to housing 110 except that it includes three windows 314a, 314b disposed in the groove 322 formed in the outer surface 320 of the housing 310. The bearing elements 350 and windows 314a, 314b are arranged in a “U” configuration. As shown, window 314a formed in the housing 310 and is not aligned with an opposing window on the other side of the bore 313. Instead, window 314a and thus the bearing element 350 disposed therein opposes a portion of a surface defining bore 313. Windows 314b and the bearing elements 350 disposed therein, however, oppose one another. A retaining member 370 is disposed in the groove 322 to retain the bearing elements 350 within the housing 310. As shown in FIG. 3, the pin 330 is similar to pin 130, in that the shaft 332 of the pin 330 has a cross-section that resembles a square with rounded edges 336 between the flat bearing surfaces 334. The shaft 332 also includes a surface 335 opposite of the bearing surface 334 facing the bearing element 350 disposed in window 314a. This surface 335 does not engage a bearing element 350 and faces the surface of the bore 313. The surface 335 may be round or flat. Similarly to support assembly 100, the bearing elements 350 are arranged in the housing 310 such that the outer surface 356 of each roller 354 is parallel with a corresponding bearing surface 334 of the pin 330. This arrangement maintains the angular orientation of the pin 330, and thus the head (not shown), as the pin 330 moves axially between a retracted and extended position because the opposing surfaces of the pin 330 and rollers 354 will contact one another in the event that the pin 330 tries to rotate. Maintaining the angular orientation of the pin 330 keeps the support surface of the head (not shown) aligned with the substrate and housing 310.

The support assembly 300 may alternatively have only two bearing elements 350 in each set. For example, the window 314a and the bearing element 150 disposed therein may be eliminated, leaving two bearing elements 350 that restrain rotation of the pin 330.

The housing 310, the pin 330, and the bearing elements 350, such as the roller 354, may each be made of a ceramic material.

FIG. 4 illustrates a partial cross-sectional view of an exemplary support assembly 400 showing a set of bearing elements 450 arranged to restrain the rotation of a pin 430. The housing 410 of the support assembly 400 includes a window 414 for each bearing element 450, the windows 414 being formed in a triangular arrangement in the housing 410 within a groove 422 formed in the outer surface 420 of the housing 410. The support assembly 400 includes one or more sets of bearing elements 450 disposed in the windows 414 in a triangular configuration. The individual bearing elements 450 are similar to bearing elements 150. Each set of bearing elements 450 in the support assembly 400 has three bearing elements in a triangular arrangement rather than each bearing element having a counterpart located on the opposing side of the bore like in support assembly 100. The shaft 452 is supported within cut outs 416 formed within the groove 422. A retaining member 470 is disposed in the groove 422 to retain the bearing elements 450 within the housing 410. The shaft 432 of the pin 430 includes a cross-section that includes three flat bearing surfaces 434 in a triangular arrangement, such as being arranged at an angle of about 60 degrees from one another. In some embodiments, each flat bearing surface 434 is separated from an adjacent flat bearing surface 434 by a rounded edge of the shaft 432 of the pin 430. The bearing elements 450 are arranged, as shown in FIG. 4, such that an outer surface 456 of rollers 454 are parallel to the bearing surfaces 434 of the shaft 432. Each flat bearing surface 434 is configured to engage with an outer surface 456 of a corresponding bearing element 450 to guide the axial movement of the pin 430. In some embodiments, the bearing elements 450 may be arranged such that the outer surfaces 456 are arranged 60 degrees from one another.

The engagement of the bearing elements 450 and corresponding bearing surfaces 434 maintain the angular orientation of the pin 430 as the pin 430 is moved between an extended and retracted position to keep the support surface of the head (not shown) aligned with the substrate and housing 410. The angular orientation is maintained because the opposing surfaces of the pin 430 and rollers 454 will contact one another in the event that the pin 430 tries to rotate.

The housing 410, the pin 430, and the bearing elements 450, such as the roller 454, may each be made of a ceramic material.

In some embodiments, the shaft 432 of the pin 430 may have a hexagonal cross-section similar to pin 730 shown in FIG. 7. The bearing elements 450 are arranged to engage the hexagonal pin to guide the axial movement of the hexagonal pin shaft.

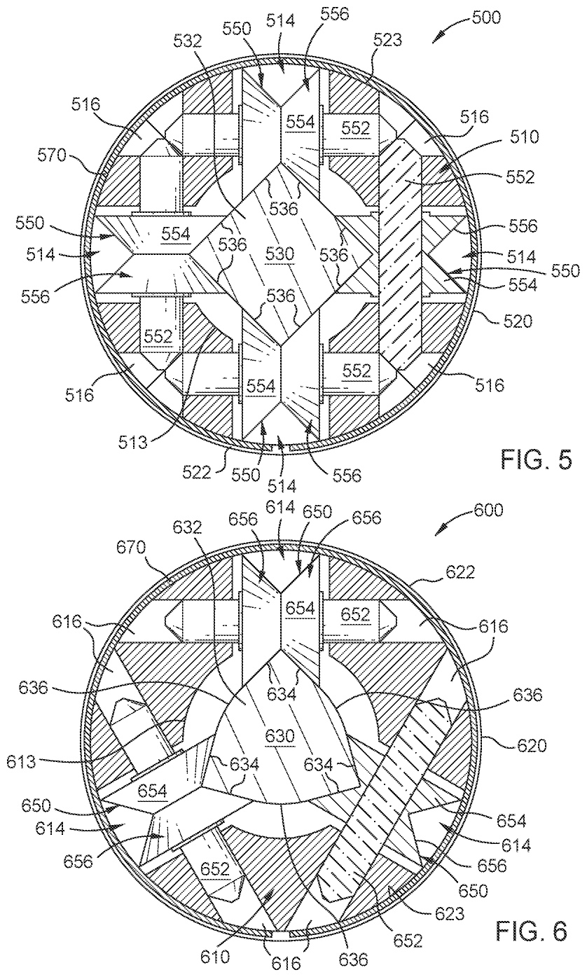

FIGS. 5 and 6 illustrate alternative embodiments of a support assembly configured to maintain the angular orientation of the pin that includes bearing elements with a channel that mirrors the shape of corresponding bearing surface of the shaft of the pin.

FIG. 5 illustrates a cross-sectional view of an exemplary support assembly 500 to show one set of bearing elements 550 arranged in a diamond configuration to restrain rotation of a pin 530. Similarly to support assembly 100, each bearing element 550 is disposed with a corresponding window 514 and corresponding cut outs 516 disposed within a groove 522 formed in the outer surface 520 of the housing 510. A retaining member 570 is disposed in the groove 522 to retain the bearing elements 550 within the housing 510. A shaft 532 of the pin 530 has a diamond (e.g., square) cross-section. Each bearing element 550 engages a corresponding bearing surface 534 of the shaft 532. The bearing surfaces 534 are where the adjoining flat surface of the shaft 532 converge at an angle. In other words, the bearing surfaces 534 are the corners of the shaft 532. Each bearing element 550 is similar to bearing element 150 and includes a shaft 552 and a roller 554, but the outer surface 556 of the roller 554 is defined by a channel that mirrors the bearing surface 534 of the shaft 532 instead of being flat like outer surface 156. The outer surface 556 compliments the contour of the corresponding bearing surface 534. As shown in FIG. 5, the outer surface 556 is the outer surface of a triangular (e.g., v-shaped) channel formed in the roller 554 that mates with the bearing surface 534 (e.g., corner) of the shaft 532. The angle of the converging flat surfaces of the triangular channel (e.g., the outer surface 556) may be the same as the angle of the bearing surface 534. This arrangement of the bearing elements 550 restrains rotation of the pin 530 within the bore 513 since the pin 530 cannot freely rotate due to the engagement of the bearing elements 550 with the bearing surfaces 534 of the shaft 532. Therefore, this arrangement of bearing elements 550 and the shape of the shaft 532 maintains the angular orientation of the pin 530, and thus its head (not shown), as the pin 530 is moved axially between an extended and retracted position. The head of the pin 530 may be similar to the head 140. Maintaining the angular orientation of the pin 530 keeps the support surface of the head (not shown) aligned with the substrate and housing 510.

While the support assembly 500 is shown with four bearing element 550 engaged with a corresponding bearing surface 534 (e.g., corner) of the shaft 532, the support assembly 500 may alternatively have just two bearing elements 550 arranged at opposing corresponding bearing surface 534 (e.g., opposing corners). In some embodiments, the support assembly 500 may have three bearing elements, similarly to support assembly 300, that engage three corresponding bearing surfaces 534 of the shaft 532.

The housing 510, the pin 530, and the bearing elements 550, such as the roller 554, may each be made of a ceramic material.

FIG. 6 illustrates a cross-sectional view of an exemplary support assembly 600 to show one set of bearing elements 650 arranged in a triangular configuration to restrain the rotation of a pin 630. Similarly to support assembly 100, each bearing element 650 is disposed with a corresponding window 614 and corresponding cut outs 616 disposed within a groove 622 formed in an exterior surface 620 of the housing 610. A retaining member 670 is disposed in the groove 622 to retain the bearing elements 650 within the housing 610.

A shaft 632 of the pin 630 has a triangular cross-section with three triangular corners. FIG. 6 shows one example of a triangular cross-section, which resembles a three-point shield with three triangular corners separated by a rounded surface 636. Each bearing element 650 engages a corresponding bearing surface 634 of the shaft 632. The bearing surfaces 634 are where the adjoining flat surface of the shaft 632 converge at an angle. In other words, the bearing surfaces 634 are the triangular corners of the shaft 632. Each bearing element 650 is similar to bearing element 150 and includes a shaft 652 and a roller 654, but the outer surface 656 of the roller 654 is defined by a channel that mirrors the bearing surface 634 of the shaft 632 instead of being flat like outer surface 156.

The outer surface 656 compliments the contour of the corresponding bearing surface 634. As shown in FIG. 6, the outer surface 656 is the outer surface of a triangular (e.g., v-shaped) channel formed in the roller 654 that mates with the bearing surface 634 (e.g., corner) of the shaft 632. The angle of the converging flat surfaces of the triangular channel (e.g., the outer surface 656) may be the same as the angle of the bearing surface 634. The arrangement of the bearing elements 650 restrains rotation of the pin 630 within the bore 613 because the pin 630 cannot freely rotate due to the engagement of the bearing elements 650 with the bearing surfaces 634 of the shaft 632. Therefore, this triangular arrangement of bearing elements 650 and the triangular shape of the shaft 632 maintains the angular orientation of the pin 630, and thus its head (not shown), as the pin 630 is moved axially between an extended and retracted position. The head of the pin 630 may be similar to the head 140. Maintaining the angular orientation of the pin 630 keeps the support surface of the head (not shown) aligned with the substrate and housing 610.

In some embodiments, the shaft 632 of the pin 630 has a triangular cross-section without a curved edge between each triangular corner. For example, the cross-section of the shaft 632 may be an equilateral triangle with three completely flat sides. The bearing elements 650 and windows 614 are arranged such that the bearing elements 650 can engage a corresponding corner of the shaft 632.

FIG. 7 also illustrates an embodiment of a support assembly configured to maintain the angular orientation of the pin that includes a shaft with flat sides that engage with a corresponding flat surface of a bearing element.

FIG. 7 illustrates a cross-sectional view of an exemplary support assembly 700 showing a set of bearing elements 750 arranged to restrain the rotation of a pin 730. The housing 710 of the support assembly 700 includes a plurality of windows 714. The windows extend from the exterior side surface 720 of the housing 710 to the bore 713. Bearing elements 750 are disposed in some of the windows 714. As shown in FIG. 7, the windows 714 with the bearing elements 750 disposed within are formed in a triangular arrangement in the housing 710. In some embodiments, and as shown in FIG. 7, the housing 710 does not have a circumferential groove formed on the exterior side surface 720 of the housing 710.

The support assembly 700 includes one or more sets of bearing elements 750 disposed in the windows 714. FIG. 7 shows three bearing elements 750 arranged in a triangular configuration. The individual bearing elements 750 are similar to bearing elements 150, and include a roller 754 that rotates about a shaft 752. The shaft 752 is integral to the housing 710 rather than being inserted into cut-outs formed in the housing 710. In other words, the shaft 752 is a portion of the housing 710. The housing 710 and bearing elements 750 are formed together by additive manufacturing. Thus, the rollers 754 are retained within the windows 714 by being formed around the shaft 752. Additionally, each shaft 752 is disposed in a window 714. Thus, each shaft 752 partially defines the window 714 that the shaft 752 is disposed within.

The shaft 732 of the pin 730 includes a hexagonal cross-section that includes three flat bearing surfaces 734. Each flat bearing surface 734 is separated from an adjacent flat bearing surface 734 by a surface 736, such as the flat surface, of the shaft 732 of the pin 730. The bearing elements 750 are arranged, as shown in FIG. 7, such that an outer surface 756 of rollers 754 are parallel to the bearing surfaces 734 of the shaft 732. Each flat bearing surface 734 is configured to engage with an outer surface 756 of a corresponding bearing element 750 to guide the axial movement of the pin 730. In some embodiments, the bearing elements 750 may be arranged such that the outer surfaces 756 are arranged 60 degrees from one another.

The engagement of the bearing elements 750 and corresponding bearing surfaces 734 maintain the angular orientation of the pin 730 as the pin 730 is moved between an extended and retracted position to keep the support surface of the head (not shown) aligned with the substrate and housing 710. The angular orientation is maintained because the opposing surfaces of the pin 730 and rollers 754 will contact one another in the event that the pin 730 tries to rotate.

The housing 710 and the bearing elements 750 may be formed together by additive manufacturing. An additive manufacturing process may include, but is not limited to a process, such as a polyjet deposition process, inkjet printing process, fused deposition modeling process, binder jetting process, powder bed fusion process, selective laser sintering process, stereolithography process, vat photopolymerization digital light processing, sheet lamination process, directed energy deposition process, or other similar three-dimensional deposition process. In some embodiments, the additive material process can be used to form the housing 710 and the rollers 754 from one material or from multiple different materials.

In some embodiments, the housing 710 and rollers 754 are formed from a ceramic material and are formed together by an additive manufacturing process. For example, in three-dimensional printing, a printhead ejects droplets of a formulation (e.g., ink of printable materials, such as a printable ceramic material) onto a surface from a nozzle, then cures the droplets with a light, e.g., ultraviolet light, from a light source, such as an LED or focused lamp in the printer. In some embodiments, the housing 710 and the rollers 754 are formed from the same ceramic material. In some embodiments, the housing 710 and the rollers 754 are formed from different ceramic materials.

Forming the housing 710 and the bearing elements 750 together by additive manufacturing reduces costs and also reduces the number of components. For example, the circumferential groove and retaining member may be eliminated. Additionally, the time and expense of installing the shaft of the rollers into the cut-outs in the housing is also eliminated. In some embodiments, the housing 710 may include one or more windows in the housing 710 that a bearing element 750 is not disposed within, such as the three shown in FIG. 7. These windows 714 may be included during the manufacturing of the housing 710 and bearing elements 750 to reduce the materials cost.

FIG. 8 illustrates a cross-sectional view of exemplary processing station 800 used for processing a substrate 840. The processing station 800 may be part of a substrate processing system, such as a cluster tool, which may include a plurality of processing stations configured process the substrate. The processing station 800 includes a housing 802, a pedestal 810, support assemblies 820, a pin lift assembly 830, a source assembly 870, and a process kit assembly 880. A controller 801 is in communication with the processing station 800 and controls the one or more components of the processing station 800. An opening 806 is formed in an upper wall of the housing 802 between the pedestal 810 and the source assembly 870.

The pedestal 810 has a support plate 812 configured to support the substrate 840 during processing. A plurality of support assemblies 820 are installed in the pedestal 810. The support assemblies 820 can by any of the support assemblies 100, 300, 400, 500, 600, and 700 described herein. The support assemblies 820 are arranged in the pedestal 810 to facilitate lifting and lowering the substrate 840, such as being arranged to support the periphery of the substrate 840. A pin 822 of each support assembly 820 is connected to the pin lift assembly 830. As shown, the pin lift assembly 830 includes a hoop 832 configured to be raised or lowered relative to the pedestal 810. The pins 822 are attached to the hoop 832 and are moved axially between the extended and retracted positions by the movement of the hoop 832. Each pin 822 of the support assemblies 820 is extended and retracted to move the substrate 840 relative to the pedestal 810.

The pins 822 of the support assemblies 820 may be extended to lift the substrate 840 off the support plate 812 after processing is complete. FIG. 8 shows the support assembly 820 in extended position such that the head 824 of the pin 822, and thus the substrate 840, is above the surface of the support plate 812. A robot blade 842 from a robot in a transfer chamber (not shown) may be inserted through an opening in the processing station 800 and into the gap between the substrate 840 and the support plate 812 to retrieve the substrate 840. The support assembly 820 may be retracted to transfer the substrate 840 to the robot blade 842. Similarly, the pins 822 of the support assemblies 820 may be extended to disengage a substrate 840 from the robot blade 842 being used to introduce the substrate 840 into the processing station 800 and then moved to the retracted position to lower the substrate 840 onto the support plate 812 for processing within the processing station 800.

The pedestal 810 and the hoop 832 are moved to positions within the processing station 800 by actuators, which may include a stepper or servo motor actuated lead screw assembly, linear motor assembly, pneumatic cylinder actuated assembly or other conventional mechanical linear actuation mechanism. A seal, such as a bellows assembly 808, is used to form a seal between the outer diameter of the pedestal 810 and the housing 802 and about a portion of the pin lift assembly 830 and the housing 802 to isolate the interior of the processing station 800 from atmospheric air.

FIG. 8 illustrates the source assembly 870 adapted to perform a physical vapor deposition (“PVD”) deposition process. The exemplary source assembly 870 includes a magnetron assembly 871, a target 872, process assembly walls 873 coupled to the housing 802, a lid 874 and a sputtering power supply 875. In this configuration, a processing surface 872A of the PVD target 872 generally defines at least a portion of the upper portion of the process region 860. The magnetron assembly 871 includes a magnetron region 879 in which the magnetron 871A is rotated by use of a magnetron rotation motor 876 during processing. The target 872 and magnetron assembly 871 are typically cooled by the delivery of a cooling fluid (e.g., deionized water) to the magnetron region 879 from a fluid recirculation device (not shown). The magnetron assembly 871 includes a plurality of magnets 871B that are configured to generate magnetic fields that extend below the processing surface 872A of the target 872 to promote a sputtering process performed in the process region 860 during a PVD deposition process.

The process kit assembly 880 may include a process region shield 882, an isolation ring 883, the sealing assembly 885 which may be positioned over and/or within the opening 806 formed within the housing 802, a deposition ring (not shown), and a cover ring 886. In some embodiments, the support plate 812 contacts a portion of the process kit assembly 880, such as the sealing assembly 885, to form the process region 860. The process region 860 may be evacuated via a vacuum pump 865 coupled to a station wall 884 of the housing 802 via a first port within the station wall 884.

For example, the vacuum pump 865 may reduce the pressure within the process region 860 to a sub-atmospheric pressure on the order of about 10-3 torr. The vacuum pump 865 may be a turbopump, cryopump, roughing pump or other useful device that is able to maintain a desired pressure within the process region 860. The station wall 884 is coupled to a gas source assembly 866, and is configured to deliver one or more process gases (e.g., Ar, N₂) to the process region 860 through a plenum during processing.

The process region shield 882 is positioned on a lower portion of the station wall 884. The process region shield 882 is typically used to collect deposition sputtered from the target 872 and to enclose a portion of the process region 860. An isolation ring 883, which is formed from a dielectric material, is configured to support the target 872 and be position on the station wall 884. The isolation ring 883 is used to electrically isolate the target 872, when it is biased by the sputtering power supply 875, from the grounded station wall 884.

To process the substrate 840, the pedestal 810 is raised to a process position (not shown) from the transfer position shown in FIG. 8. When in the process position, a region of the support plate 812 forms a separable seal with a portion of the sealing assembly 885 so as to substantially fluidly isolate the process region 860 from the remainder of the interior of the processing station 800. Thus, when in the process position, the support plate 812, the sealing assembly 885, the process region shield 882, the station wall 884, the isolation ring 883 and target 872 substantially enclose and define the process region 860.

The sealing assembly 885 may include an upper plate 885a, flexible bellows 885b, and a lower plate 885c. The flexible bellows 885b is positioned between the upper plate 885a and the lower plate 885c. In some embodiments, the seal formed between the portion of the support plate 812 and the upper plate 885a of the sealing assembly 885 is created at a sealing region that is formed by physical contact between a surface of the region of the support plate 812 and a surface of the upper plate 885a. In some embodiments, the flexible bellows assembly 885b of the sealing assembly 885 is configured to be extended in the vertical direction as the portion of the support plate 812 is placed in contact with the surface of the portion of the sealing assembly 885. The compliant nature of the flexible bellows 885b assembly allows any misalignment or planarity differences between the surface of the portion of the support plate 812 and the surface of the portion of the sealing assembly 885 to be taken up so that a reliable, repeatable and separable seal can be formed. The flexible bellows assembly 885b may be a stainless steel bellows assembly or Inconel bellows assembly, among others.

While processing station 800 shown in FIG. 8 is shown as adapted to perform a PVD deposition process, the source assembly 870 can include different hardware to perform a different process. For example, the source assembly 870 may be adapted to perform chemical vapor deposition (“CVD”), plasma enhanced chemical vapor deposition (“PECVD”), atomic layer deposition (“ALD”), plasma enhanced atomic layer deposition (“PEALD”), etch, lithography, ion implantation, ashing, cleaning, thermal process (e.g., rapid thermal processing, anneal, cool down, thermal management control) degas, and/or other useful substrate processes.

The controller 801 may include a programmable central processing unit (CPU) which is operable with a memory (e.g., non-volatile memory) and support circuits. The support circuits are conventionally coupled to the CPU and comprise cache, clock circuits, input/output subsystems, power supplies, and the like, and combinations thereof coupled to the various components of the processing station 800, to facilitate control of the processing station 800. For example, in some embodiments the CPU is one of any form of general purpose computer processor used in an industrial setting, such as a programmable logic controller (PLC), for controlling various polishing system components and sub-processors. The memory, coupled to the CPU, is non-transitory and is typically one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the processing station 800. The instructions in the memory are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

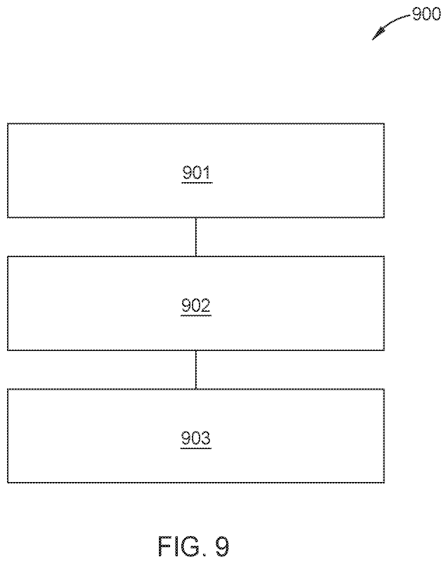

FIG. 9 illustrates a method 900 of moving a substrate within a processing station. The method 900 may be executed within processing station 800 by controller 801. As shown by activity 901, a substrate is initially positioned on a support surface of a pedestal. This substrate has been processed within the processing station, such as undergoing a PVD process within process region 860. Support assemblies within the pedestal are extended from a retracted position until the head of the pins of the support assemblies engage the substrate. Each pin is rotationally locked by a plurality of bearing elements engaged with the pin that are disposed a housing of each support assembly. The support assemblies may be any one of the support assemblies 100, 300, 400, 500, 600, and 700 described herein. For example, the bearing elements may be arranged such that a flat outer surface of a roller of each bearing element is parallel with a corresponding flat bearing surface of the pin to rotationally lock the pin. For example, the pin includes a shaft with a plurality of corners that are engaged with an outer surface of a corresponding bearing element to rotationally lock the pin, the outer surface being defined by a channel complementary to the corner of the shaft. In some embodiments, the support assemblies may be arranged around a periphery of the substrate such that each support surface of each head engages a bottom edge of the substrate.

As shown by activity 902, the pins of the support assemblies are further moved to the extended position to lift the substrate above the pedestal. This movement may be continuous with activity 901, or the upward movement of the pins may be halted once the pins come into contact with the substrate prior to moving the pins to the extended position. Lifting the substrate above the pedestal allows a robot, such as the blade of a robot, to be positioned between the underside of the substrate and the support surface of the pedestal.

As shown by activity 903, the substrate is disengaged from the support surface of the pins. The substrate may be disengaged using the robot to lift the substrate above the support surface of the pins. In some embodiments, the pins may be retracted to lower the substrate onto the robot. Continued lowering of the pins will disengage the substrate from the pins and leave the substrate supported on the robot.

In some embodiments, each bearing element is configured to engage with a sharp corner of as shaft in which the corner is where two flat surfaces engage at a point. In some embodiments, each bearing element is configured to engage with a rounded corner of the shaft.

A method of moving a substrate, comprising extending a plurality of pins of a plurality of support assemblies from a retracted position to engage a bottom edge of a substrate that is engaged with a support surface of a pedestal, wherein each pin is rotationally locked by a plurality of bearing elements engaged with the pin that are disposed within a housing of each support assembly. The method further comprising extending the plurality of pins to an extended position lift the substrate above the pedestal. The method further comprising disengaging the substrate from the plurality of lift pins in the extended position.

In one embodiment of the method of moving the substrate, the bearing elements are arranged such that a flat outer surface of a roller of each bearing element is parallel with a corresponding flat bearing surface of the corresponding pin to rotationally lock the pin.

In one embodiment of the method of moving the substrate, the pin includes a shaft with a plurality of corners that are engaged with an outer surface of a corresponding bearing element to rotationally lock the pin, wherein the outer surface of the bearing elements is defined by a channel complementary to the corner of the shaft.

While the foregoing is directed to embodiments of the present disclosure, other and further embodiments of the disclosure may be devised without departing from the basic scope thereof, and the scope thereof is determined by the claims that follow.

What is claimed is:

1. A support assembly for supporting a substrate in a processing station, comprising:
a housing including a bore, a groove formed on an exterior surface of the housing, and a plurality of windows disposed in the groove that intersect the bore;
a pin disposed in the bore and moveable between a retracted position and an extended position, wherein the pin includes a shaft including a plurality of bearing surfaces;
a plurality of bearing elements at least partially disposed in a corresponding window of the plurality of windows, wherein each bearing element includes an outer surface configured to engage a corresponding bearing surface of the shaft, wherein the plurality of bearing elements and bearing surfaces cooperate to maintain an angular orientation of the pin as the pin moves between the retracted position and the extended position; and
a retaining member disposed in the groove.

2. The support assembly of claim 1, wherein the plurality of bearing surfaces comprise four flat bearing surfaces arranged in a square configuration and the plurality of bearing elements comprises four bearing elements arranged in a square configuration.

3. The support assembly of claim 1, wherein the plurality of bearing surfaces comprises three flat bearing surfaces arranged in a triangular configuration, wherein each flat bearing surface is separated from an adjacent bearing surface by a rounded edge of the shaft.

4. The support assembly of claim 1, wherein the plurality of bearing surfaces comprise a corner of a shaft and the outer surface of the bearing elements is defined by a channel complementary to the corner of the shaft.

5. The support assembly of claim 4, wherein the plurality of bearing surfaces comprise four bearing surfaces and the plurality of bearing elements comprise four bearing elements arranged in a diamond configuration.

6. The support assembly of claim 4, wherein the plurality of bearing surfaces comprise three bearing surfaces and the plurality of bearing elements comprise three bearing elements arranged in a triangular configuration.

7. The support assembly of claim 1, wherein the pin includes a head that extends beyond a periphery of the shaft, the head comprising a support surface configured to engage a bottom edge of a substrate.

8. The support assembly of claim 1, wherein the housing, the pin, and rollers of the bearing elements are formed from a ceramic material.

9. The support assembly of claim 1, wherein a lower end of the shaft of the pin is connected to a pin lift assembly configured to move the pin between the extended position and the retracted position.

10. The support assembly of claim 1, wherein the housing includes a shoulder at an upper end configured to engage with a surface of a pedestal.

11. A support assembly for supporting a substrate in a processing station, comprising:
a ceramic housing including a bore, a groove formed on an exterior surface of the ceramic housing, a plurality of windows disposed in the groove that intersect the bore, and a shoulder at an upper end configured to engage with a surface of a pedestal;
a ceramic pin disposed in the bore and moveable between a retracted position and an extended position, wherein the ceramic pin includes a shaft including a plurality of bearing surfaces and a head with a supporting surface configured to engage with a bottom edge of a substrate;
a plurality of bearing elements at least partially disposed in a corresponding window of the plurality of windows, wherein each bearing element includes a ceramic roller with an outer surface configured to engage a corresponding bearing surface of the shaft, wherein the plurality of bearing elements and bearing surfaces cooperate to maintain the support surface in alignment with the bottom edge of the substrate as the ceramic pin moves between the retracted position and the extended position; and
a retaining member disposed in the groove.

12. The support assembly of claim 11, wherein the plurality of bearing surfaces comprise four flat bearing surfaces arranged in a square configuration and the plurality of bearing elements comprises four bearing elements arranged in a square configuration.

13. The support assembly of claim 11, wherein the plurality of bearing surfaces comprises three flat bearing surfaces arranged in a triangular configuration, wherein each flat bearing surface is separated from an adjacent bearing surface by a rounded edge of the shaft.

14. The support assembly of claim 11, wherein the plurality of bearing surfaces comprise a corner of a shaft and the outer surface of the bearing elements is defined by a channel complementary to the corner of the shaft.

15. The support assembly of claim 14, wherein the plurality of bearing surfaces comprise four bearing surfaces and the plurality of bearing elements comprise four bearing elements arranged in a diamond configuration.

16. The support assembly of claim 14, wherein the plurality of bearing surfaces comprise three bearing surfaces and the plurality of bearing elements comprise three bearing elements arranged in a triangular configuration.

17. The support assembly of claim 16, wherein a rounded surface of the shaft is disposed between adjacent bearing surfaces.

18. A support assembly for supporting a substrate in a processing station, comprising:
a ceramic housing including an outer surface, an inner surface defining a bore, and a plurality of first windows extending from the outer surface and the inner surface;
a ceramic pin disposed in the bore and moveable between a retracted position and an extended position, wherein the ceramic pin includes a pin shaft including a plurality of bearing surfaces and a head with a supporting surface configured to engage with a bottom edge of a substrate; and
a plurality of bearing elements at least partially disposed in a corresponding window of the plurality of first windows, wherein each bearing element includes a bearing shaft formed integrally with the ceramic housing and a ceramic roller with an outer surface configured to engage a corresponding bearing surface of the pin shaft, wherein the plurality of bearing elements and bearing surfaces cooperate to maintain the support surface in alignment with the bottom edge of the substrate as the ceramic pin moves between the retracted position and the extended position.

19. The support assembly of claim 18, wherein the pin shaft has a hexagonal cross-section.

20. The support assembly of claim 18, wherein the plurality of bearing surfaces comprises three flat bearing surfaces, wherein each flat bearing surface is separated from an adjacent bearing surface by a flat edge of the pin shaft.
